(19) United States
(12) Patent Application Publication
(10) Pub. No.: US 2025/0293127 A1
(43) Pub. Date: Sep. 18, 2025

(54) LEADFRAME PANEL, A SEMICONDUCTOR PACKAGE COMPRISING A LEADFRAME WITH A TWO-LEVEL DAMBAR DESIGN AND A METHOD FOR FABRICATING THE SAME

(71) Applicant: Infineon Technologies AG, Neubiberg (DE)

(72) Inventors: Wei Kian CHO, Melaka (MY); Chii Shang HONG, Melaka (MY); Ke Yan TEAN, Melaka (MY); Chwee Pang TOMMY KHOO, Melaka (MY); Chee Mun WAI, Melaka (MY)

(73) Assignee: Infineon Technologies AG, Neubiberg (DE)

(21) Appl. No.: 19/051,289

(22) Filed: Feb. 12, 2025

(30) Foreign Application Priority Data
Mar. 18, 2024 (DE) 10 2024 107 572.4

(51) Int. Cl. H01L 23/495; H01L 21/48

(52) U.S. Cl. CPC H01L 23/49555; H01L 21/4842; H01L 23/49503

(57) ABSTRACT

A leadframe panel is disclosed. In one example, the leadframe panel comprises a plurality of leadframes wherein each one of the plurality of leadframes comprises a die pad and a first plurality of leads. The leads are arranged side by side along a row on a first side of the die pad. At least a first outermost lead is connected with the die pad. A first dambar which connects all leads with each other. A second dambar, which is connected with the first outermost lead. The first dambar and the second dambar are located within one and the same plane and the second dambar is located at a different position than the first dambar in relation to the die pad.

### CROSS-REFERENCE TO RELATED APPLICATION

This Utility Patent application claims priority to German Patent Application No. 10 2024 107 572.4 filed Mar. 18, 2024, which is incorporated herein by reference.

### TECHNICAL FIELD

The present disclosure is related to a leadframe panel, to a semiconductor package, and to a method for fabricating the semiconductor package.

### BACKGROUND

In the manufacture of semiconductor component packages, large-format leadframe panels are often used, which contain a large number of individual interconnected lead frames. Each of the individual lead frames contains at least one die pad and a large number of leads or other types of external contacts. Such a large-format leadframe panel is fed one after the other to various processing stations, in which all the individual leadframes it contains are subjected to various treatments in parallel processing. In one processing station, for example, semiconductor dies are applied to the die pads of the lead frames. In a subsequent processing station, bonding wires are attached between various connection points. And again in another subsequent processing station, each of the individual lead frames is encapsulated by applying a moulding material.

It is easy to imagine that problems can occur in one of these processing stations that make further processing difficult or even impossible. Such a problem has been discovered by the inventors and forms the basis of the present disclosure.

### SUMMARY

A first aspect of the present disclosure is related to a leadframe panel, comprising a plurality of leadframes wherein each one of the plurality of leadframes comprises a die pad and a first plurality of leads, wherein the leads are arranged side by side along a row on a first side of the die pad, wherein at least a first outermost lead is connected with the die pad, a first dambar which connects all leads with each other, and a second dambar which is connected with the first outermost lead, wherein the first dambar and the second dambar are located within one and the same plane and the second dambar is located at a different position than the first dambar in relation to the die pad.

A second aspect of the present disclosure is related to a semiconductor package, comprising a leadframe comprising a die pad and a first plurality of leads; and a semiconductor die disposed on the die pad, wherein the leads are arranged side by side along a row on a first side of the semiconductor device package, wherein a first outermost lead which is arranged at a first outermost position of the first plurality of leads, comprises a structure which is different from the structure of other leads, wherein at least the first outermost lead is connected with the die pad, and wherein each one of the leads comprises a first dambar residual which is located at a first upper level, and the first outermost lead comprises in addition a second dambar residual which is located at a second lower level.

A third aspect of the present disclosure is related to a method for fabricating a semiconductor device package, the method comprising providing a leadframe panel according to the first aspect, attaching semiconductor dies to the die pads of the leadframes, encapsulating the leadframes and cutting the first dambar between the leads, singulating the leadframes, and bending the outer ends of the leads.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description.

The elements of the drawings are not necessarily to scale relative to each other. Like reference numerals designate corresponding similar parts.

FIG. 1 shows in its upper section a conventional leadframe panel or strip and in its lower section a graph showing the warpage of the leadframe panel after mounting semiconductor dies onto the die pads by a diffusion soldering process.

FIG. 2 shows a section of a leadframe panel according to an embodiment and an enlarged section thereof.

FIG. 3 shows a section of a leadframe panel according to an embodiment and an enlarged section thereof which in addition to FIG. 2 also shows a semiconductor die pad and auxiliary structures for connecting with the second and third dambars.

FIG. 4 comprises FIGS. 4A, 4B, and 4C and shows a top view (A), a perspective view (B), and an enlarged section of the perspective view (C) on a semiconductor package according to an embodiment.

FIG. 5 comprises a flow diagram of a method for fabricating a semiconductor device package according to an embodiment.

### DESCRIPTION OF EMBODIMENTS

In the past, during fabrication processes of certain package types, it was increasingly found that the die pads of the lead frames can warp during the application of a semiconductor die to the die pad due to CTE mismatch between the semiconductor die and the die pad. The semiconductor die is usually applied to the die pad by diffusion soldering. The higher the soldering temperature is set, the greater the resulting warpage of the die pad. The warpage of the die pads results in a warpage of the entire leadframe panel, which subsequently cannot be further processed. The problem occurred in particular when semiconductor dies made of SiC were applied to copper die pads by diffusion soldering and is caused by the different CTEs of SiC and Cu, but is of course also conceivable for other constellations.

For these and other reasons there is a need for the present disclosure.

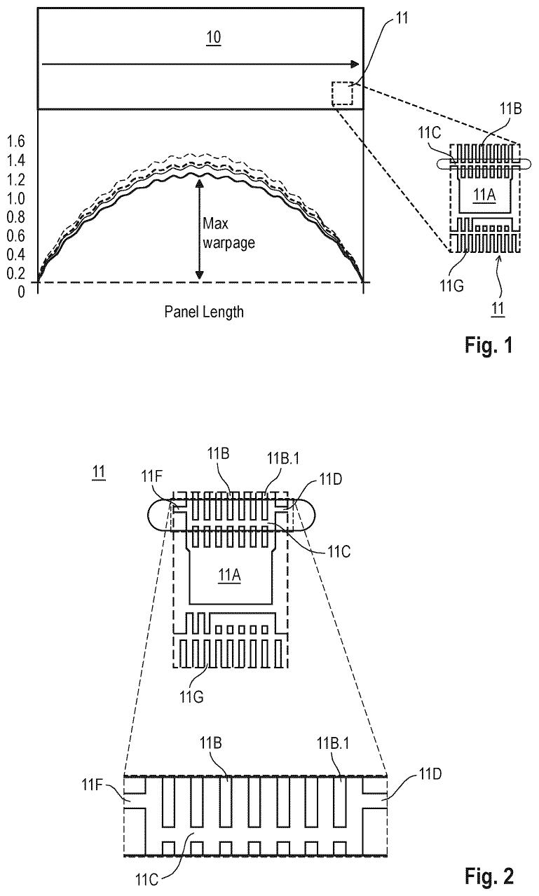

FIG. 1 illustrates the initial problem described above. It shows in its upper section a large frame around a conventional leadframe panel or strip 10 comprising a plurality of single interconnected leadframes 11, one of them being shown in an enlarged section in a small frame at the right, and in its lower section a graph showing the warpage of the leadframe panel after mounting semiconductor dies onto the die pads by a diffusion soldering process.

As can be seen in the enlarged section of FIG. 1, each one of the leadframes 11 comprises a central die pad 11A and a first plurality of leads 11B which are connected with the die pad 11A and arranged side by side along a row on a first upper side of the die pad 11A. A lateral dambar 11C interconnects all leads 11B of the first plurality of leads 11B with each other. The leadframe 11 further comprises a second plurality of leads which are arranged side by side along a row on a second lower side of the die pad 11A. They are intended to be connected by wire bonds with contact pads on an upper surface of a semiconductor die to be attached to the die pad 11A in later process steps.

FIG. 1 shows in its lower section a graph showing the measurement of warpage of the leadframe panel 10 after mounting semiconductor dies onto the die pads. The resulting curve is the leadframe coilset measurement data after a diffusion solder process performed at a temperature of 410° C. However, other high-temperature application methods as, for example, soft soldering with high bond force setting are also conceivable to lead to similar results. The warpage has been simulated by only assuming a certain CTE value between the semiconductor die and the die pad and neglecting gravity. The resulting curves were assumed to be taken under room temperature on the top surface of the leadframe panel at the tiebar area after the die attach process. The curves refer to different types of TOLT packages. The warpages of the individual leadframes can be recognized in each curve, wherein the warpages accumulate to a warpage of the entire leadframe panel. The dambar is a critical structure in TOLT leadframe panel as it transfers the unit level warpage to the strip level warpage. The maximum warpage occurs in the center of the leadframe panel.

A first aspect of the present disclosure is related to a leadframe panel, comprising a plurality of leadframes wherein each one of the plurality of leadframes comprises a die pad and a first plurality of leads, wherein the leads are arranged side by side along a row on a first side of the die pad, wherein at least a first outermost lead is connected with the die pad, a first dambar which connects all leads with each other, and a second dambar which is connected with the first outermost lead, wherein the first dambar and the second dambar are located within one and the same plane and the second dambar is located at a different position than the first dambar in relation to the die pad.

According to an embodiment of the leadframe panel of the first aspect, the second dambar is located at a position further away from the die pad than the first dambar. Alternatively it is also possible to locate the second dambar nearer to the die pad than the first dambar.

As will be shown below, this construction serves to break the intrinsic stress that was generated from the die pad level to the leadframe level as the die pad warpage is transferred to leadframe tiebar through the leads.

According to an embodiment of the leadframe panel according to the first aspect, the leadframe panel further comprises a first auxiliary structure, wherein the second dambar is connected between the first outermost lead and the first auxiliary structure. The first auxiliary structure can in principle be any supporting component of the leadframe like, for example a simple metal piece connecting one individual leadframe to another neighboring leadframe. It will not be part of the individual leadframe packaged in the final semiconductor package.

According to an embodiment of the leadframe panel according to the first aspect, the leadframe panel further comprises a second outermost lead which is arranged at a second outermost position of the plurality of leads, a third dambar, which is connected with the second outermost lead, wherein the first dambar and the third dambar are located within one and the same plane and the third dambar is located at a different position than the first dambar in relation to the die pad. Otherwise, the same conditions may be met as described above in connection with the second dambar.

Also in connection with the afore-mentioned embodiment, the leadframe panel may further comprise a second auxiliary structure, wherein the third dambar is connected with the second auxiliary structure. The same conditions as described above in connection with the first auxiliary structure may also apply to the second auxiliary structure.

This embodiment therefore means that the second and third dambars are positioned symmetrically on opposite sides of the pad. This allows the intrinsic stress of the leadframe to be broken even better.

According to an embodiment of the leadframe panel according to the first aspect, not only the outermost leads but each one of the leads is connected with the die pad.

According to an embodiment of the leadframe panel according to the first aspect, the leadframe panel further comprises a second plurality of leads wherein the leads are arranged side by side along a row on a second side of the die pad which second side is located opposite to the first side. According to an example thereof the leadframe panel further comprises a fourth dambar which connects all leads with each other.

According to an embodiment of the leadframe panel of the first aspect, each leadframe of the leadframe panel is a preform of a TO-Leaded top-side cooling (TOLT) package.

According to an embodiment the leadframe panel of the first aspect, each leadframe of the leadframe panel is made of copper or a copper alloy. According to an example thereof, the leadframes comprise a coating of Ni, Ni/NiP, Ni/NiNiP, or any other suitable coating.

A second aspect of the present disclosure is related to a semiconductor package, comprising a leadframe comprising a die pad and a first plurality of leads; and a semiconductor die disposed on the die pad, wherein the leads are arranged side by side along a row on a first side of the semiconductor device package, wherein a first outermost lead which is arranged at a first outermost position of the first plurality of leads, comprises a structure which is different from the structure of other leads, wherein at least the first outermost lead is connected with the die pad, and wherein each one of the leads comprises a first dambar residual which is located at a first upper level, and the first outermost lead comprises in addition a second dambar residual which is located at a second lower level.

According to an embodiment of the semiconductor device package of the second aspect, a second lead of the first plurality of leads, comprises a third dambar residual which is located at the second lower level. The second lead can be an outermost lead located opposite to the first outermost lead. In another embodiment, the first outermost lead and the second lead are arranged on the same side of the semiconductor package.

According to an embodiment of the semiconductor device package of the second aspect, one or both of the second dambar residual of the first outermost lead or the third dambar residual of the outermost lead comprise a trapezoidal cross-section.

According to an embodiment of the semiconductor device package of the second aspect, wherein each one of the leads comprises a first upper horizontal portion, a bent portion, and a second lower horizontal portion, wherein the first dambar of the leads is located in the first upper horizontal portion, and the second dambar of the first outermost lead and the third dambar of the second outermost lead are located in the bent portion.

According to an embodiment of the semiconductor device package of the second aspect, wherein each one of the leads comprises a first upper horizontal portion, a bent portion, and a second lower horizontal portion, wherein the first dambar residual of the leads is located in the bent portion, and the second dambar residual of the first outermost lead and the third dambar residual of the second outermost lead are located in the lower horizontal portion or partially overlap with the bent portion.

It is important to note that in both afore mentioned embodiments the first dambar residual on the one hand and the second and third dambar residuals on the other hand are not positioned along the same straight line.

According to an embodiment of the semiconductor device package of the second aspect, each one of the first plurality of leads is connected with the die pad. In one embodiment, “connected” means that the first plurality of leads and the die pad are made by a same piece of metal and there is no fabricated junction between the leads and the die pad.

According to an embodiment of the semiconductor device package of the second aspect, the package further comprises a second plurality of leads wherein the leads are arranged side by side along a row on a second side of the semiconductor device package which second side is located opposite to the first side.

According to an embodiment of the semiconductor device package of the second aspect, the second plurality of leads are identically formed and comprise a dambar residual which is located at a first upper level.

According to an embodiment of the semiconductor device package of the second aspect, the semiconductor die comprises a semiconductor transistor die.

According to an embodiment of the semiconductor device package of the second aspect, the semiconductor die comprises one or more of a horizontal semiconductor transistor die, a vertical semiconductor transistor die, a semiconductor power transistor die, an IGBT die, a MOSFET die, a CoolMOS die, a wide band gap semiconductor transistor die, in particular a SiC transistor die or a GaN transistor die.

According to an embodiment of the semiconductor device package of the second aspect, the package can be any kind of SMD package. One example thereof is of the type of a TO-Leaded top-side cooling (TOLT) package.

According to an embodiment of the semiconductor package of the second aspect, the leadframe is made of copper or a copper alloy. According to an example thereof, the leadframe comprises a coating of Ni, Ni/NiP, Ni/NiNiP, or any other suitable coating.

A third aspect of the present disclosure is related to a method for fabricating a semiconductor device package, the method comprising providing a leadframe panel according to the first aspect, attaching semiconductor dies to the die pads of the leadframes, encapsulating the leadframes and cutting the first dambar between the leads, singulating the leadframes, and bending the outer ends of the leads.

In the following detailed description, reference is made to the accompanying drawings, which form a part hereof, and in which is shown by way of illustration specific embodiments in which the disclosure may be practiced. In this regard, directional terminology, such as “top”, “bottom”, “front”, “back”, “leading”, “trailing”, etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

It is to be understood that the features of the various exemplary embodiments described herein may be combined with each other, unless specifically noted otherwise.

As employed in this specification, the terms “bonded”, “attached”, “connected”, “coupled” and/or “electrically connected/electrically coupled” are not meant to mean that the elements or layers must directly be contacted together; intervening elements or layers may be provided between the “bonded”, “attached”, “connected”, “coupled” and/or “electrically connected/electrically coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected”, “coupled” and/or “electrically connected/electrically coupled” elements, respectively.

Further, the word “over” used with regard to a part, element or material layer formed or located “over” a surface may be used herein to mean that the part, element or material layer be located (e.g. placed, formed, deposited, etc.) “indirectly on” the implied surface with one or more additional parts, elements or layers being arranged between the implied surface and the part, element or material layer. However, the word “over” used with regard to a part, element or material layer formed or located “over” a surface may, optionally, also have the specific meaning that the part, element or material layer be located (e.g. placed, formed, deposited, etc.) “directly on”, e.g. in direct contact with, the implied surface.

Moreover, the word “exemplary” is used herein to mean serving as an example, instance, or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or multiple” unless specified otherwise or clear from context to be directed to a singular form. Also, at least one of A and B or the like generally means A or B or both A and B.

FIG. 2 shows a section of a leadframe panel according to an embodiment and an enlarged section thereof.

The leadframe panel 10 as shown in FIG. 2 comprises
a plurality of leadframes 11 wherein each one of the plurality of leadframes 11 comprises a die pad 11A and a first plurality of leads 11B, 11B.1. The first plurality of leads 11B, 11B.1 are arranged side by side along a row on a first upper side of the die pad 11A and are connected with the die pad 11A. The first plurality of leads 11B, 11B.1 comprise a first outermost lead 11B.1 on the right hand side. A first dambar 11C connects all leads 11B, 11B.1 with each other. The leadframe panel 10 further comprises a second dambar 11D which is connected with the first outermost lead 11B.1. On the opposite side of the leadframe 11 a third dambar 11F is shown which is connected with a second outermost lead 11B.2. The leadframe 11 further comprises a second plurality of leads 11G which are arranged side by side along a row on a second lower side of the die pad 11A.

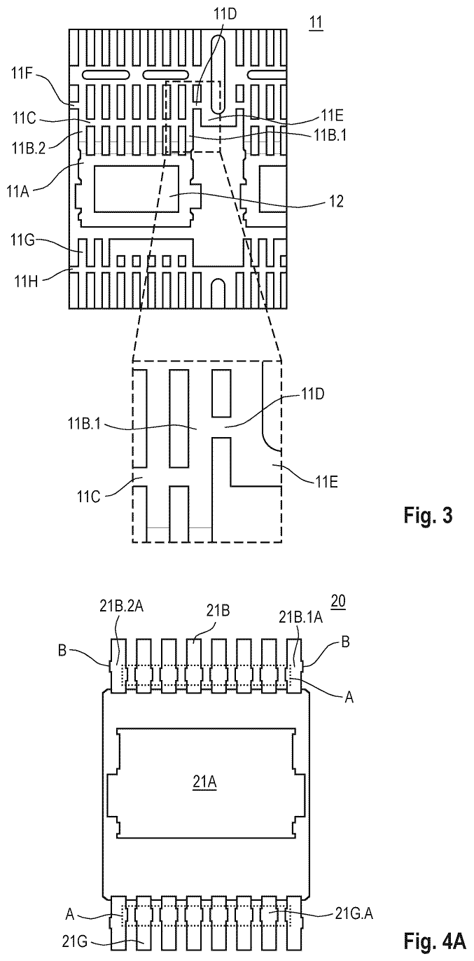

FIG. 3 shows a section of a leadframe panel according to an embodiment and an enlarged section thereof which in addition to FIG. 2 also shows a semiconductor die pad and auxiliary structures for connecting with the second and third dambars.

The leadframe panel 10 as shown in FIG. 3 can be the same as that shown in FIG. 2 so that most of the reference numerals are retained here. In addition a semiconductor die 12 attached to the die pad 11. In addition to that a first auxiliary structure 11E is, wherein the second dambar 11E is connected between the first outermost lead 11B.1 and the first auxiliary structure 11E. On the opposite side of the leadframe 11 a third dambar 11F is shown which is connected between the second outermost lead 11B.2 and a second auxiliary structure (not shown).

As indicated by the arrow in the enlarged section, the second dambar 11D is shifted to a different position than the first dambar 11C in relation to the die pad 11A. More specifically, the second dambar 11D is located at a position further away from the die pad 11A than the first dambar 11C. The distance between the first dambar 11C and the second dambar 11D can be in a range of, for example, 1 mm to 2 mm. The first auxiliary structure 11E forms a mechanical connection between the leadframe 11 and a neighboring leadframe on the right side.

The leadframe 11 may further comprise a second outermost lead 11B.2 which is arranged at a second outermost position of the plurality of leads 11B, 11B.1, 11B.2, a third dambar 11F, and a second auxiliary structure (not shown), wherein the third dambar 11F connects the second outermost lead 11B.2 with the second auxiliary structure. The structure and connection between the second outermost lead 11B.2 and the second auxiliary structure can look exactly like that between the first outermost lead 11B.1 and the first auxiliary structure 11E and is merely arranged mirror-symmetrically to it.

The leadframe 11 may further comprise a second plurality of leads 11G wherein the leads 11G are arranged side by side along a row on a second side of the die pad 11A which second side is located opposite to the first side. The second plurality of leads 11G is intended to be connected with contact pads disposed on an upper surface of the semiconductor die in the fabricated semiconductor package. According to an example thereof, the leadframe 11 may further comprise a fourth dambar 11H which connects all leads 11G with each other.

Each leadframe 11 of the plurality of lead frames 11 can be designed in this way as shown in FIGS. 2 and 3. In this way, the intrinsic stresses that were generated from the die pad level to the leadframe level can be broken for each one of the leadframes. and the processing of the leadframe panel can be continued.

Referring again to FIG. 1, the lead frame panel 10 is moved from left to right as indicated by the arrow. It might be enough in this stage of the process to lift up only the most right lead of the first leadframe and also with all the following leadframes only lifting up their most right leads in order to move the leadframe panel correctly into the next equipment. However, it could turn out to be necessary to lift up the most right lead and the most left lead of the leadframes. In the above embodiments, only the top row of leads 11B, 11B.1 and 11B.2 are described with the additional dambars 11D/11F, for the lower row of leads which not physically connect to the die pad, the dambar can be arranged in a conventional way, because the lower row of leads are not physically connected to the die pad, therefore the warpage of die pad will not transfer to the lower row of leads. However it is also practical in some embodiments that the lower row of leads has the similar arrangement of different dambars alike the top row of leads. This may bring the easy manufacturing of leadframe panel.

The semiconductor transistor die 12 can be, for example, one or more of a vertical transistor die, a power transistor die, an IGBT die, a MOSFET die, a CoolMOS die, or a SiCMOS die, a wide band gap semiconductor transistor die, in particular a SiC transistor die or a GaN transistor die. The semiconductor transistor die 12 furthermore comprises a drain pad on its lower main surface, the drain pad thus electrically connected with the die pad 11A, furthermore a source pad, a gate pad and possibly also a source/sense pad (pads not shown), all of these disposed on the upper main surface of the semiconductor transistor die 12.

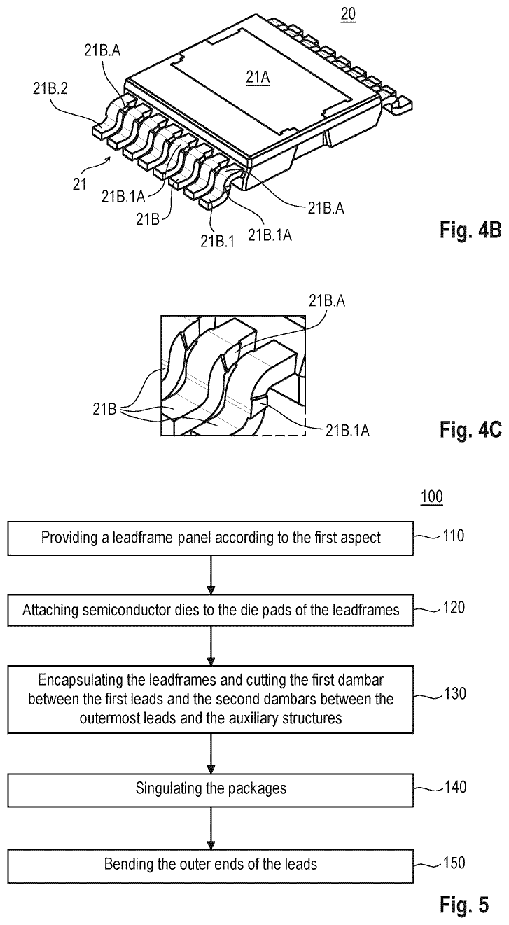

FIG. 4 comprises FIGS. 4A, 3B, and 4C and shows a top view (A), a perspective view (B), and an enlarged section of the perspective view (C) on a semiconductor device package according to an embodiment.

The semiconductor device package 20 of FIG. 4 comprises a leadframe 21 comprising a die pad 21A and a first plurality of leads 21B, 21B.1, and a semiconductor transistor die (not shown) disposed on the die pad 21A. The leads 21B, 21B.1 are connected with the die pad 21A and are arranged side by side along a row on a first side of the semiconductor device package 20. A first outermost lead 21B.1 which is arranged at a first outermost position of the first plurality of leads 21B, 21B.1 comprises a structure which is different from the structure of other leads 21B. In particular, each one of the leads 21B, 21B.1 comprises a first dambar residual 21B.A which is located at a first upper level A (see FIG. 4A), and the first outermost lead 21B.1 comprises in addition a second dambar residual 21B.1A which is located at a second lower level B (see FIG. 4A).

The first dambar residual 21B.A results from the first dambar 11C shown in FIG. 2, and the second dambar residual 21B.1A results from the second dambar 11D shown in FIG. 2. The first outermost lead 21B.1 has two dambar residual, one is 21B.A at the same level with its neighboring lead, and another one is 21B.1A which is at a different level.

The semiconductor device package 20 further comprises a second outermost lead 21B.2 which is arranged at a second outermost position of the plurality of leads. The second outermost position is located opposite the first outermost position. The second outermost lead 21B.2 comprises a first dambar residual 21B.A which results from the first dambar 11C shown in FIG. The second outermost lead 21B.2 furthermore comprises a third dambar residual 21B.2A which is located at the second lower level B (see FIG. 3A) and which results from the third dambar 11F shown in FIGS. 2 and 3.

One or both of the second dambar residual 21B.2A of the first outermost lead 21B.1 or the third dambar residual 21B.2A of the second outermost lead 21B.2 comprise a trapezoidal cross-section which results from the bending process of the leads. The original respective dambar originally had a rectangular cross-section.

As shown in FIG. 4, each one of the leads 21B, 21B.1, and 21B.2 comprises a first upper horizontal portion, a bent portion, and a second lower horizontal portion, wherein the first dambar residual 21B.A of the leads 21B, 21B.1 is located in the first upper horizontal portion, and the second dambar residual 21B.1A of the first outermost lead 21B.1 and the third dambar residual 21B.2A of the second outermost lead 21B.2 are located in the bent portion.

However, it is alternatively also possible that the first dambar residual 21B.A of the leads 21B, 21B.1 is located in the bent portion, and the second dambar residual 21B.1A of the first outermost lead 21B.1 and the third dambar residual 21B.2A of the second outermost lead 21B.2 are located in the lower horizontal portion or partially overlap with the bent portion.

The semiconductor device package 20 may further comprise a second plurality of leads 21G wherein the leads 21G are arranged side by side along a row on a second side of the semiconductor device package 20 which second side is located opposite to the first side. According to an example thereof, the leads 21G are identically formed and comprise a dambar residual 21G.A which is located at an upper level A (see FIG. 3A). The dambar residual 21G.A results from the fourth dambar 11H shown in FIGS. 2 and 3.

The semiconductor transistor die may comprise one or more of a vertical transistor die, a power transistor die, an IGBT die, a MOSFET die, a CoolMOS die, a SiCMOS die, a wide band gap semiconductor transistor die, in particular a SiC transistor die or a GaN transistor die.

The semiconductor package 20 as shown in FIG. 4 is an example of a TOLT package. It should be appreciated, however, that the present disclosure is also applicable to other kinds of semiconductor device packages.

FIG. 5 comprises a flow diagram of a method for fabricating a semiconductor device package according to an embodiment.

The method 100 comprises providing a leadframe panel according to the first aspect (110), attaching semiconductor dies to the die pads of the leadframes (120), encapsulating the leadframes and cutting the first dambar between the leads (130), singulating the packages (140), and bending the outer ends of the leads (150).

The bending of the leads may be performed such that it results in a semiconductor device package as shown in FIG. 4, in particular so that each one of the leads comprises a first upper horizontal portion, a bent portion, and a second lower horizontal portion.

### EXAMPLES

In the following specific examples of the present disclosure are described.

Example 1 is a leadframe panel, comprising a plurality of leadframes wherein each one of the plurality of leadframes comprises a die pad and a first plurality of leads, wherein the leads are arranged side by side along a row on a first side of the die pad, wherein at least a first outermost lead is connected with the die pad, and a first dambar which connects all leads with each other, a second dambar which is connected with the first outermost lead, wherein the first dambar and the second dambar are located within one and the same plane and the second dambar is located at a different position than the first dambar in relation to the die pad).

Example 2 is the leadframe panel according to Example 1, wherein the second dambar is located at a position further away from the die pad than the first dambar.

Example 3 is the leadframe panel according to Example 1 or 2, further comprising a first auxiliary structure, wherein the second dambar is connected between the first outermost lead and the first auxiliary structure.

Example 4 is the leadframe panel according to any one of the preceding Examples, further comprising a second outermost lead which is arranged at a second outermost position of the plurality of leads, and a third dambar which is connected with the second outermost lead, wherein the first dambar and the third dambar are located within one and the same plane and the third dambar is located at a different position than the first dambar in relation to the die pad.

Example 5 is the leadframe panel according to Example 4, further comprising a second auxiliary structure, wherein the third dambar is connected between the second outermost lead and the second auxiliary structure.

Example 6 is the leadframe panel according to any one of the preceding Examples, wherein each one of the first plurality of leads is connected with the die pad.

Example 7 is the leadframe panel according to any one of the preceding Examples, further comprising a second plurality of leads wherein the leads are arranged side by side along a row on a second side of the die pad which second side is located opposite to the first side.

Example 8 is the leadframe panel according to Example 7, further comprising a fourth dambar which connects all leads with each other.

Example 9 is a semiconductor package, comprising a leadframe comprising a die pad and a first plurality of leads, and a semiconductor transistor die disposed on the die pad, wherein the leads are arranged side by side along a row on a first side of the semiconductor device package, wherein a first outermost lead which is arranged at a first outermost position of the first plurality of leads, comprises a structure which is different from the structure of other leads, wherein at least the first outermost lead is connected with the die pad, and wherein each one of the leads comprises a first dambar residual which is located at a first upper level, and the first outermost lead comprises in addition a second dambar residual which is located at a second lower level.

Example 10 is the semiconductor package according to Example 9, wherein a second lead of the first plurality of leads comprises a third dambar residual which is located at the second lower level.

Example 11 is the semiconductor package according to Example 9 or 10, wherein one or both of the second dambar residual of the first outermost lead or the third dambar residual of the second lead comprise a trapezoidal cross-section.

Example 12 is the semiconductor package according to any one of Examples 9 to 11, wherein each one of the leads comprises a first upper horizontal portion, a bent portion, and a second lower horizontal portion, wherein the first dambar residual of the leads is located in the first upper horizontal portion, and the second dambar residual of the first outermost lead and the third dambar residual of the second outermost lead are located in the bent portion.

Example 13 is the semiconductor package according to any one of Examples 9 to 11, wherein each one of the leads (21B, 21B.1, 21B.2) comprises a first upper horizontal portion, a bent portion, and a second lower horizontal portion, wherein the first dambar residual (21B.A) of the leads (21B, 21B.1) is located in the bent portion, and the second dambar residual (21B.1A) of the first outermost lead (21B.1) and the third dambar residual (21B.2A) of the second outermost lead (21B.2) are located in the lower horizontal portion or partially overlap with the bent portion.

Example 14 is the semiconductor package according to any one of Examples 9 to 13, wherein each one of the leads is connected with the die pad.

Example 15 is the semiconductor package according to any one of examples 9 to 14, further comprising a second plurality of leads wherein the leads are arranged side by side along a row on a second side of the semiconductor device package which second side is located opposite to the first side.

Example 16 is the semiconductor package according Example 15, wherein the leads are identically formed and comprise a dambar residual which is located at a first upper level.

Example 17 is the semiconductor package according to any one of Examples 9 to 16, wherein the semiconductor transistor die comprises one or more of a vertical semiconductor transistor die, a semiconductor power transistor die, an IGBT die, a MOSFET die, a CoolMOS die, a wide band gap semiconductor transistor die, in particular a SiC transistor die or a GaN transistor die.

Example 18 is a method for fabricating a semiconductor device package, the method comprising providing a leadframe panel according to any one of Examples 1 to 8, attaching semiconductor dies to the die pads of the leadframes, encapsulating the leadframes and cutting the first dambar between the leads and the second dambars between the outermost leads and the auxiliary structures, singulating the packages, and bending the outer ends of the leads.

In addition, while a particular feature or aspect of an embodiment of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Furthermore, it should be understood that embodiments of the disclosure may be implemented in discrete circuits, partially integrated circuits or fully integrated circuits or programming means. Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

1. A leadframe panel, comprising:
a plurality of leadframes wherein each one of the plurality of leadframes comprises a die pad and a first plurality of leads;
wherein the leads are arranged side by side along a row on a first side of the die pad, wherein at least a first outermost lead is connected with the die pad;
a first dambar which connects all leads with each other; and
a second dambar which is connected with the first outermost lead, wherein the first dambar and the second dambar are located within one and the same plane and the second dambar is located at a different position than the first dambar in relation to the die pad;
characterized in that the second dambar is located at a position further away from the die pad than the first dambar.

2. The leadframe panel according to claim 1, further comprising:
a first auxiliary structure, wherein the second dambar is connected between the first outermost lead and the first auxiliary structure.

3. The leadframe panel according to claim 1, further comprising:
a second outermost lead which is arranged at a second outermost position of the plurality of leads; and
a third dambar which is connected with the second outermost lead, wherein the first dambar and the third dambar are located within one and the same plane and the third dambar is located at a different position than the first dambar in relation to the die pad.

4. The leadframe according to claim 3, further comprising:
a second auxiliary structure, wherein the third dambar is connected between the second outermost lead and the second auxiliary structure.

5. The leadframe panel according to claim 1, wherein
each one of the first plurality of leads is connected with the die pad.

6. The leadframe panel according to claim 1, further comprising:
a second plurality of leads wherein the leads are arranged side by side along a row on a second side of the die pad which second side is located opposite to the first side.

7. The leadframe panel according to claim 6, further comprising:
a fourth dambar which connects all leads with each other.

8. A semiconductor package, comprising:
a leadframe comprising a die pad and a first plurality of leads; and
a semiconductor transistor die disposed on the die pad;
wherein the leads are arranged side by side along a row on a first side of the semiconductor device package, wherein a first outermost lead which is arranged at a first outermost position of the first plurality of leads, comprises a structure which is different from the structure of other leads,
wherein at least the first outermost lead is connected with the die pad, and
wherein each one of the leads comprises a first dambar residual which is located at a first upper level, and the first outermost lead comprises in addition a second dambar residual which is located at a second lower level.

9. The semiconductor package according to claim 8, wherein
a second lead of the first plurality of leads comprises a third dambar residual which is located at the second lower level.

10. The semiconductor package according to claim 8, wherein
one or both of the second dambar residual of the first outermost lead or the third dambar residual of the second lead comprise a trapezoidal cross-section.

11. The semiconductor package according to claim 8, wherein
each one of the leads comprises a first upper horizontal portion, a bent portion, and a second lower horizontal portion, wherein
the first dambar residual of the leads is located in the first upper horizontal portion, and the second dambar residual of the first outermost lead and the third dambar residual of the second outermost lead are located in the bent portion.

12. The semiconductor package according to claim 8, wherein
each one of the leads comprises a first upper horizontal portion, a bent portion, and a second lower horizontal portion,
wherein the first dambar residual of the leads is located in the bent portion, and the second dambar residual of the first outermost lead and the third dambar residual of the second outermost lead are located in the lower horizontal portion or partially overlap with the bent portion.

13. The semiconductor package according to claim 8, wherein
each one of the leads is connected with the die pad.

14. The semiconductor package according to claim 8, further comprising:
a second plurality of leads wherein the leads are arranged side by side along a row on a second side of the semiconductor device package which second side is located opposite to the first side.

15. The semiconductor package according to claim 14, wherein
the leads are identically formed and comprise a dambar residual which is located at a first upper level.

16. The semiconductor package according to claim 8, wherein
the semiconductor transistor die comprises one or more of a vertical semiconductor transistor die, a semiconductor power transistor die, an IGBT die, a MOSFET die, a CoolMOS die, a wide band gap semiconductor transistor die, in particular a SiC transistor die or a GaN transistor die.

17. A method for fabricating a semiconductor device package, the method comprising:
providing a leadframe panel according to claim 1;
attaching semiconductor dies to the die pads of the leadframes;
encapsulating the leadframes and cutting the first dambar between the leads and the second dambars between the outermost leads and the auxiliary structures;
singulating the packages; and
bending the outer ends of the leads.
